(19) United States
(12) Patent Application Publication
(10) Pub. No.: US 2003/0142838 A1
(43) Pub. Date: Jul. 31, 2003

(54) Frequency synthesiser

(76) Inventors: Paul Brennan, East Barnet (GB); Ian Thompson, Camberley (GB); Assaad Borjak, Sunbury on Thames (GB)

Correspondence Address: COHEN, PONTANI, LIEBERMAN & PAVANE, 551 FIFTH AVENUE, SUITE 1210, NEW YORK, NY, 10176, US

(21) Appl. No.: 10/203,838

(22) PCT Filed: Feb. 14, 2001
(86) PCT No.: PCT/GB01/00604

(30) Foreign Application Priority Data
Feb. 17, 2000 (GB) 0003740.8

(51) Int. Cl. H03G 5/00

(52) U.S. Cl. 381/98

(57) ABSTRACT

A frequency synthesiser (50) comprising input means for receiving a reference frequency (FreF) and output means for providing a desired output frequency (fo). The synthesiser comprises further means (58) for dividing the desired output frequency by a plurality of divider values. The division is accomplished based on pre-generated control data for controlling the dividing of the desired output frequency by the divider values in accordance with the desired output frequency. The control data is stored in memory means (62) of the synthesiser.

### FIELD OF THE INVENTION

The present invention relates to a synthesiser and in particular but not exclusively to a synthesiser for use in elements of a telecommunications network.

### BACKGROUND TO THE INVENTION

Synthesisers are used to generate signals of a given frequency. This frequency signal is often mixed with a received signal to down convert the received signal to a lower frequency or mixed with a signal to be transmitted to convert the signal to a higher frequency, in wireless telecommunication applications.

Reference is made to FIG. 1, which shows a known synthesiser. The synthesiser receives a reference signal Fref. The reference signal Fref is input to a phase detector 2. The phase detector 2 compares the reference frequency Fref with a feedback value Ffeedback. The phase detector 2 generates an error signal based on the comparison. The error signal is input to a filter 4, which is typically a low pass filter. The low pass filter removes higher order frequencies. The output of the loop filter, which is the filtered error signal, is input to a voltage controlled oscillator 6. The output of the low pass filter 4 is in the form of a voltage signal. The voltage controlled oscillator 6 provides an output frequency fo. The output frequency provided by the voltage controlled oscillator 6 is determined by the value of the filtered error signal.

The output frequency of the voltage controlled oscillator is then used as required. The output frequency of the voltage controlled oscillator 6 is also fed back to a dual modulus divider 8. The dual modulus divider 8 toggles between division ratios of N and N+1. N is an integer. The output frequency fo is always greater than the reference frequency Fref. For example, if the output frequency fo is 5.5 times the value of the reference frequency Fref, N will be 5 and N+1 will be 6. By controlling the toggling between 5 and 6, it is possible to ensure that the mean value applied to the voltage controlled oscillator 6 will be such that the output frequency fo is 5.5 times the reference frequency Fref. The dual, modulus divider 8 is controlled by a sigma delta logic block 10. The logic block 10 generates bit values, which control the toggling between N and N+1. The sigma delta logic block 10 has a channel select input, which controls the bit pattern output by the sigma delta logic block 10. A different bit pattern will be output for example if the output frequency fo is 5.5×Fref as compared to when the output frequency is 5.25×Fref. The output of the dual modulus divider is of frequency fo divided by the average of N and N+1 taking into account the relative frequencies of those values. This value is Ffeedback. This first part of the circuit is a phase locked loop. This value is also input to the sigma delta logic block 10 and acts as a clock signal.

Reference is now made to FIG. 2, which shows one example of the sigma delta logic block 10 of FIG. 1 in more detail. The sigma delta logic block 10 has an input from a channel select which determines the required output frequency fo. This input comprises a value between 0 and 1. The input from the channel select is input to a first summer 12, which sums the output of a first delay element 13 and a second delay element 14. The first delay element 13 is a feedback delay element, which is connected to the output of the summer 12. The second delay element 14 has its input connected to the output of the sigma delta logic loop. The output of the second delay element 14 is in fact subtracted from the sum of the channel select input and the output of the first delay element 13.

The output of the first summer 12 is input to a second summer 16. The second summer 16 also receives a first weight input 18 and an output from a third delay element 20. The weight input 18 is generated from a first weight A and the output of the second delay element 14. The third delay element 20 has its input connected to the output of the second summer 16.

A third summer 24 is connected to the output of the second summer 16. The third summer 24 receives an input from a fourth delay element 22, the input of which is connected to the output of the third summer 24. The third summer 24 also receives an input from a second weighting unit 26 the output of which is governed by a second weight B and the output of the second delay element 14.

The output of the third summer 24 is input to a one bit quantiser. This converts the output of the summer into a 0 or a 1. This provides the output which is used to control the dual modulus divider 8.

The function of the sigma-delta loop 10, in this example of the sigma-delta architecture, is to provide an output to counters (not shown) dual modulus divider 8. The output has a mean value equivalent to the digital word input, whilst shaping the quantisation noise according to a third order high pass function. This can provide a fractional mean division ratio with low close-in phase noise at the expense of increased phase noise further from the carrier where it can be readily suppressed by the phase lock loop part, constituted by the phase detector, loop filter, voltage controlled oscillator and dual modulus divider.

However, this arrangement does suffer from a number of disadvantages.

Firstly, there is a limited operating speed. The sigma delta bit sequence is generated in real time. Accordingly, the speed at which the bit sequence can be generated is limited by technology limits on the speed of digital adders (the summers). Furthermore, because the known arrangement generates the values in real time, the power consumption is relatively high. This is disadvantageous where there is a limited power supply available.

Secondly, in order to achieve a relatively fast operation, the sigma delta loop usually operates with truncated non optimal integer values for weights A and B which can result in short limit cycles under certain conditions which means that the control of the divider is not as good as it could be. Additionally, the use of integer weights also reduces the design flexibility. Similarly, the adder resolution is limited by hardware constraints.

Typically, these synthesisers are used to generate a range of frequencies. However, a third disadvantage is that the weights which are used will not be optimal for each frequency. Accordingly, the weights A and B will be better with some frequencies than other frequencies.

A fourth disadvantage is that the arrangement must remain unconditionally stable. This means that it can not be ensured that the loop provides the required output all the time. If the sequence output by the loop is not correct, the voltage controlled oscillator will generate the wrong output frequency and/or operate with poor spectral purity.

A further disadvantage is that the phase of the output of the voltage controlled oscillator will not be the same each time the frequency is changed. Accordingly, phase coherent operation is not possible. New output phases are biased by previous fractional inputs to this block resulting in an indeterminate setting phase of the synthesizer.

EP 0 098 138 describes a frequency synthesiser comprising a sequence generator for generating a sequence to be applied to a frequency divider. The frequency divider comprises a P counter, an A counter, and N adder and an N counter. The output signal from the signal generator is separated into two separate signals; one signal is input into the A counter and the other signal is input into the N adder. The P counter is capable of counting to either P or P+1 under the control of an output signal from the A counter.

### SUMMARY OF THE INVENTION

It is an aim of embodiments of the present invention to address one or more of the above problems.

According to one aspect of the present invention, there is provided a frequency synthesizer comprising input means for receiving a reference frequency; output means for providing a desired output frequency; memory means for stoning pre-generated control data for controlling division of the desired output frequency by a plurality of divider values in accordance with the desired output frequency: and means for dividing the desired output frequency by the plurality of divider values based on said pre-generated control data stored in the memory means.

### BRIEF DESCRIPTION OF THE DRAWINGS

For a better understanding of the present invention and as to how the same may be carried into effect, reference will now be made by way of example to the accompanying drawings in which:

FIG. 1 shows a known synthesiser;

FIG. 2 shows one example of a sigma delta logic block of the synthesiser of FIG. 1;

FIG. 3 shows a first synthesiser embodying the present invention;

FIG. 4 shows a second synthesiser embodying the present invention;

FIG. 5 shows a third synthesiser embodying the present invention;

FIG. 6 shows a fourth synthesiser embodying the present invention;

FIG. 7 shows a schematic view of a typical wireless cellular telecommunications network; and

FIG. 8 shows a base transceiver station incorporating the synthesiser of any of FIGS. 3 to 6.

### DETAILED DESCRIPTION OF EMBODIMENTS OF THE INVENTION

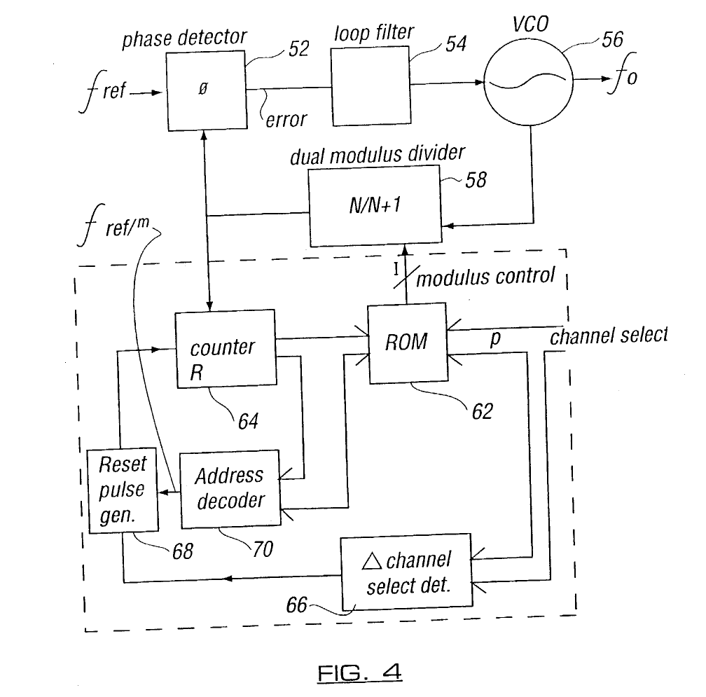

Reference is made to FIG. 3 which shows a first synthesiser 50 embodying the present invention.

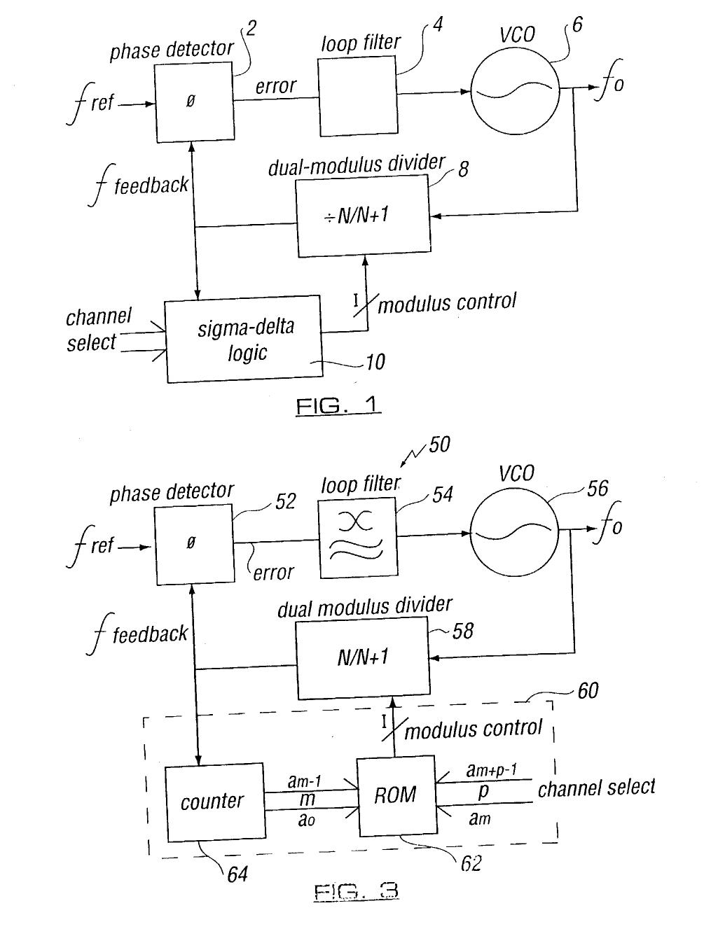

The synthesiser 50 has an input for a reference frequency Fref. The input frequency is input to a phase detector 52, which operates in a similar manner to that described in relation to FIG. 1. The phase detector compares the phase of the reference frequency Fref with that of the feedback frequency Ffeedback. As with the prior art, an error signal is output by the phase detector 52, which is input to a loop filter 54 The loop filter 54 is a low pass filter 54 which takes out higher frequencies which may be introduced for example by the phase detector, the dual modulus divider and any of the other components of the circuit. The loop filter 54 cleans up the error signal so that it excludes the unwanted higher frequencies. The error signal is an analogue signal and can be in the form of a voltage. This voltage is applied to a voltage controlled oscillator 56. The frequency output by the voltage controlled oscillator 56 is controlled by the output of the loop filter 54. The output of the voltage controlled oscillator 56 is the output frequency fo. This represents the desired frequency, phase locked to the reference signal Fref.

The output of the voltage controlled oscillator 56 is also fed back to a dual modulus divider which again toggles between division ratios of N and N+1, where N is an integer under the control of a control block 60.

The control block 60 comprises a memory 62, which in the present example is a ROM. However, it should be appreciated that any other suitable type of memory can be used instead of or even as well as the ROM 62. The memory may be a RAM, which is loaded once at power up or constantly updated as required.

For each frequency that is to be generated by the voltage controlled oscillator 56, a bit sequence is stored. In the embodiment of the invention, the bit sequence comprises 2^{m} bits and the number of available frequencies is 2^{p}. The frequency to be output by the voltage controlled oscillator 56 is selected via the channel select address. This effectively selects a row or column of the ROM. The values in the row or column of the ROM for the selected frequency are output one bit at a time, in sequence, under the control of a counter 64. The counter has m outputs to address each of the 2^{m} bits which are successively output. The frequency or channel selector provides p inputs to the ROM so that the 2^{p} frequencies are selectable. The counter 64 is controlled by a clock signal generated by the output of the dual modulus divider 58.

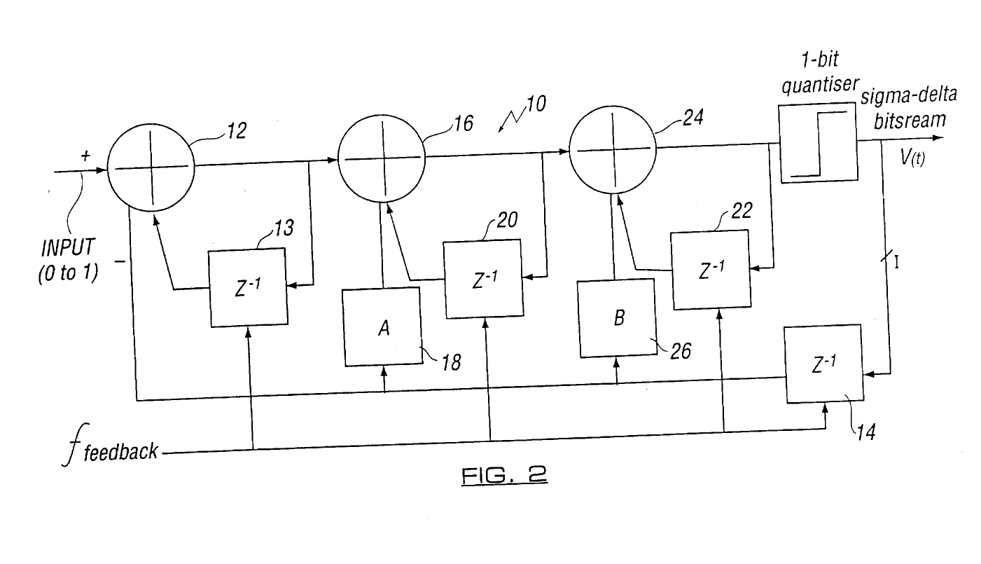

Accordingly, in embodiments of the present invention, the sigma delta loop of the prior art arrangement, described in relation to FIGS. 1 and 2, is replaced by a counter 64 and a memory 62. Pre-generated bit sequences are clocked out of the memory 62. Embodiments of the present invention can provide sigma delta bit sequences or any other type of bit sequences using any other technique capable of achieving the desired noise-shaping.

The bit sequences are generated offline, for example by the simulation of a given sigma delta loop. This arrangement has the advantage that bit sequences can be individually optimised, on a frequency by frequency basis. It is also very easy to generate a bit sequence which is optimised for the application of the synthesiser. For example, the bit sequences for different frequencies can be modelled using different sigma delta architectures so that the most appropriate architecture is used for each frequency. In the models used, more complex non-integer weights can be used as there is no requirement to do the modelling in real time. Additionally, greater resolutions can be achieved. Loops with alternative feedback structures can also be used as there is no time constraint on the modelling of the bit sequences.

By multiplexing an 8 bit or 16 bit wide ROM for example the bit sequence can be output from the ROM at a very fast rate. Accordingly, the limiting factor on the speed of the arrangement is no longer the sigma delta logic loop but rather the speed of other elements in the synthesizer.

The output of the dual modulus divider 58, controlled in accordance with the output of the ROM 62 is input to the phase detector 52 and to the counter 64. The dual modulus divider 58, will when it receives the value 1, divide the output of the voltage controlled oscillator 56 by N and when the divider 58 receives the value 0 divide the output of the voltage controlled oscillator by N+1. Of course, N and N+1 may be associated with the values 0 and 1 respectively. The output of the dual modulus divider is thus the output frequency fo divided by the average of the sum of N and N+1 taking into account the number of times that each of those values occur. In other words, the output frequency is divided by a value which is between N and N+1 inclusively. This feedback frequency is used to control the counter 64 and also is fed back to the phase detector 52 and used to generate the error signal.

A substantial improvement in phase noise is possible due to the 1/Fref factor arising from sampling theory and operation further down the high pass sigma delta noise shaping. Additionally, reference side bands are likely to be completely outside the operating band of the synthesiser. Finally, stability is not a problem since any unstable bit sequences are rejected at the simulation stage and are not written into the ROM.

Reference is made to FIG. 4 which shows a second embodiment of the present invention. The synthesiser of FIG. 4 in fact includes the elements of FIG. 3 with the addition of a further three elements. The same reference numbers are used for the same elements in FIGS. 3 and 4.The frequency selection input is provided not only to the ROM 62 but also to a channel selection detector 66 which detects when the channel changes. The channel selection detector 66 detects when the selected frequency or channel has been changed. When this has occurred, the channel selection detector 66 provides an output to a reset pulse generator 68. The reset pulse generator 68 is controlled by the output of an address decoder 70. The address decoder receives the output of the counter 64 and generates a virtual reference frequency. This virtual reference frequency is, in preferred embodiments of the invention, an integer sub multiple of the reference frequency Fref, equivalent to the required output frequency resolution of the synthesizer. The output of the address decoder 70, providing the virtual reference, causes the reset pulse generator 68 to generate a reset pulse. The reset pulse generated by the reset pulse generator 68 is input to the counter which starts once again from the beginning of the selected bit sequence.

In particular, the address decoder 70 provides an output signal with a rising edge periodically. The frequency of this rising edge is the virtual reference frequency and occurs every x counts of the counter. The rising edge causes the reset pulse generator to generate a reset signal if a channel change has just been detected. Because the frequency of the signal output by the address decoder is an integer sub multiple of the reference frequency it can be determined that when the counter is reset, the signal output by the divider and hence the synthesizer will always have a known phase. The second rising edge after the channel change is detected, causes the reset signal to be zero.

This arrangement allows phase coherent operation to be achieved, which has not previously been achieved with known arrangements. This is achieved firstly by deriving the virtual reference frequency by means of the address decoder 70 attached to the counter output. This virtual reference in turn resets the counter via the reset generator in synchronism with the rising edge of the signal, shortly after a change in the desired channel occurs.

Additionally, in order to allow phase coherent operation, the bit sequences which are stored provide equal or very similar transfer phase between the input and the output of the dual modulus divider. In other words, the dual modulus divider does not alter or only slightly alters the phase of the signal passing there through. In practice, this can be achieved by the use of a simple algorithm which calculates the phase of a given bit sequence. In other words, the bit sequence can be tested before it is stored in the ROM.

Finally, the arrangement is designed so that cycle slipping rarely occurs, by means of a sufficiently wide loop bandwidth and/or the use of coarse pre-steering of the VCO.

The embodiments of the present invention have used a voltage controlled oscillator. However in alternative embodiments of the invention, a current controlled oscillator or the like may be used.

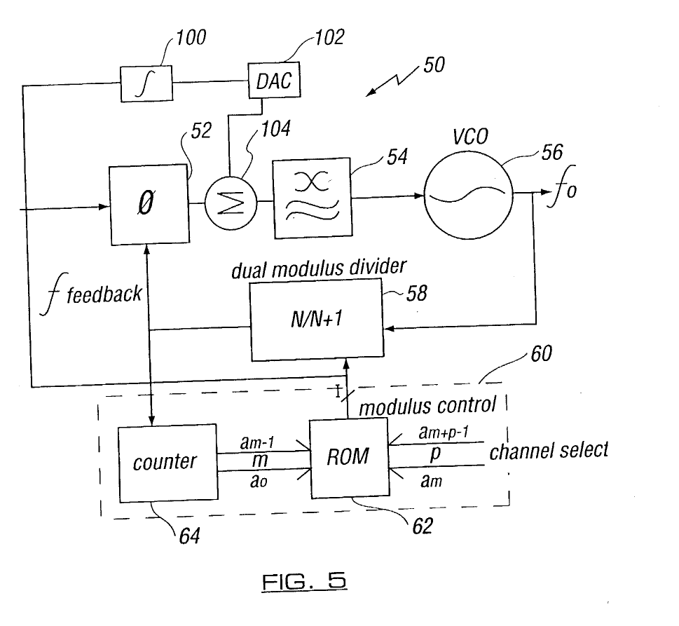

Reference is made to FIG. 5 which shows a further embodiment of the present invention. Those components which are the same as in FIGS. 3 and 4 are referenced by the same numerals. The embodiment shown in FIG. 5 has the elements of the embodiment of FIG. 3 with the addition of an integrator 100, a digital to analogue converter 102 and a summer 104. The integrator 100 is arranged to receive the output of the ROM 62. The integrator 100 integrates the output of the ROM 62 and provides a digital output which is converted to an analogue form by the digital to analogue converter 102. The output of the digital to analogue converter 102 is input to the summer 104, which subtracts that output from the output of the phase detector 52. The output of the summer 104 is input to the low pass filter. This further loop provided in this embodiment removes the modulation element from the error signal caused by switching of the dual modulus divider values by subtracting the modulation component from the error signal output by the phase detector 52.

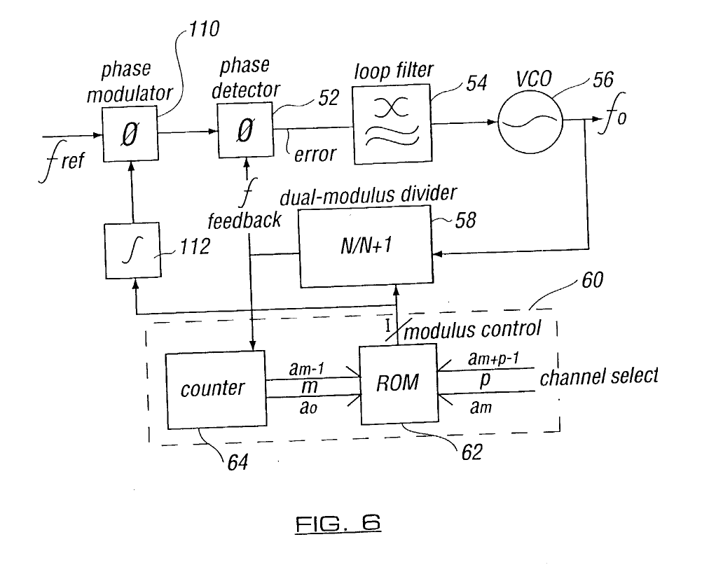

Reference is made to FIG. 6 which shows a further embodiment of the present invention. In this embodiment, a phase modulator 110 and an integrator 112 are also provided. The phase modulator 110 is connected between the input provided by the reference frequency Fref and the input to the phase detector 52. The phase modulator also receives an input from the integrator 112 which in turn receives the output of the ROM 62. The output of the ROM 62 is integrated by the integrator 112 which may also provide a delay. This integrated output is input to the phase modulator 110.

The arrangement of FIG. 6 is arranged to achieve the same effect as the arrangement of FIG. 5. However in the embodiment shown in FIG. 6, the phase modulator 110 introduces a inverse modulation component, opposite to that introduced by the divider. When the phase detector receives the output of the divider 58 and the output of the modulator 110 and compares them, the modulation component of the output of the divider is cancelled by the inverse modulation component introduced by the modulator 110. Accordingly, the phase detector outputs only an error signal without any modulation.

The integrators of FIGS. 5 and 6 can be replaced by any other suitable element which provides the same, similar or different mathematical operation.

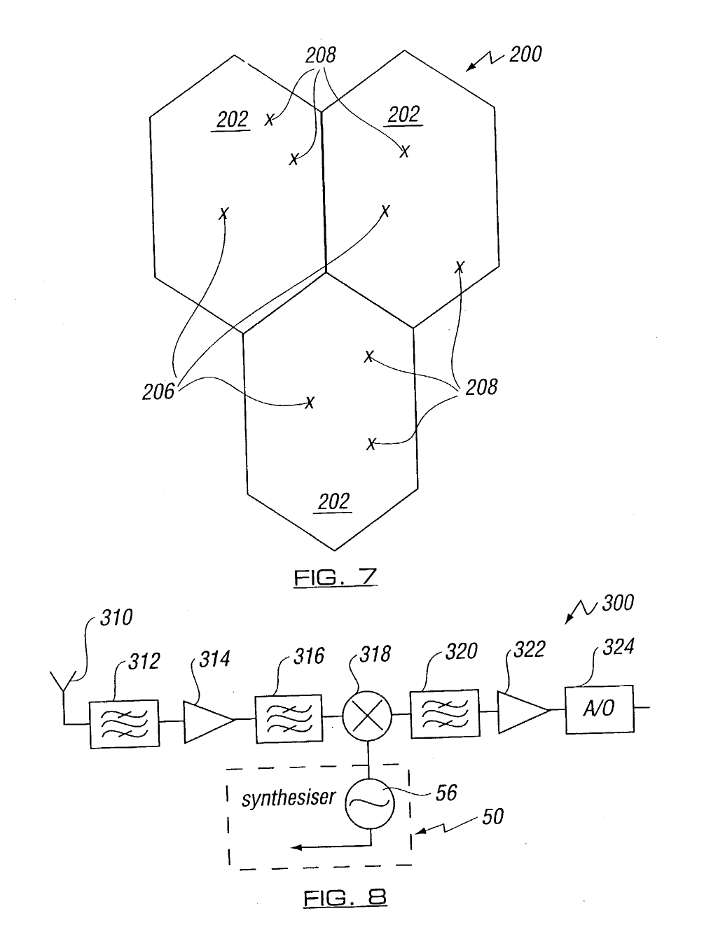

Reference is now made to FIG. 7, which shows a known cellular telecommunications network in which embodiments of the present invention may be used. The area covered by the network 200 is divided into a plurality of cells 202. Each cell 202 is served by a base transceiver station 206, which is arranged to transmit signals to and receive signals from terminals 208 located in the cell 202 associated with the respective base transceiver station 206. The terminals 208 may be mobile stations which are able to move between the cells.

Each base transceiver station is, in the GSM standard (Global System for Mobile communications) arranged to receive and transmit on a different number of frequencies. This is because the GSM standard uses a time division multiple access technique. In the GSM standard, each channel has a bandwidth of 200 KHz, which is one example of the virtual reference discussed previously.

Reference is made to FIG. 8, which shows part of a typical base transceiver station 300. In this Figure, only the receive part of the base transceiver station 300 is shown. The base transceiver station 300 has an antenna 310, which is arranged to receive signals from mobile stations in the cell served by the base transceiver station 208. Depending on the construction of the base transceiver station, a receive part such as shown in FIG. 8 may be provided for each channel (or frequency) which is received by the base station 300 at the same time. Only one receive part is in fact shown in FIG. 8. It should be appreciated that more complex arrangements may be used in which a single receive part is able to receive all of the frequencies at the same time.

The receive part has a first band pass filter 312 which is arranged to filter out signals which fall outside the receive band in which the available channels are located. The filtered output is input to a first low noise amplifier 314 which amplifies the receive signals. The amplified signal is then passed through a second band pass filter 316 which filters out any noise, such as harmonics or the like introduced by the first amplifier 314. The output of the second band pass filter 316 is connected to a mixer 318 which receives the output of a voltage controlled oscillator. This voltage controlled oscillator can be the voltage controlled oscillator 56 of the synthesizer of FIGS. 3 to 6. The remainder of the synthesiser is the arrangement shown in any of the embodiments of FIGS. 3, 4, 5 or 6 which controls the frequency provided by the voltage controlled oscillator 56. The mixer mixes the output of the voltage controlled oscillator 56 with the output of the second band pass filter 316 to provide a down converted signal. That down converted signal may be at the intermediate frequency or the base band frequency, depending on the construction of the receive part. The output of the mixer is connected to the input of a third band pass filter 320 which acts as the intermediate frequency filter, providing narrow-band filtering of the signal. The output of the band pass filter 320 is input to a second amplifier 322 which amplifies the signal. The amplified output of the second amplifier 322 is converted to a digital signal by an analogue to digital converter 324.

It should be appreciated that base transceiver stations will have a transmit part, similar to that shown in FIG. 8. In particular, there will be up conversion of signals from the base band frequency either directly to the radio frequency or to the intermediate frequency. For either or both of those up conversions, the arrangement shown in FIGS. 3 to 6 may be used to generate the mixing frequency which is input to the respective mixer.

In the GSM standard, frequency hopping is sometimes used. This means that the frequency of the channel which is used will change with time. The arrangement shown in FIGS. 3 to 6 can be used to control the voltage controlled oscillator 56 such that the required reference frequency is provided for the channel which is used. In alternative embodiments of the present invention, the frequency of a channel may remain unchanged. Accordingly, the frequency provided by a given voltage controlled oscillator will be unchanged.

Embodiments of the present invention are particularly advantageous in telecommunication systems. This is because the communications take the form of data bursts which typically last for the order of 100's of microseconds. The bit stream provided can have a length comparable to the burst period in some embodiments of the present invention, which is particular advantageous. However, in alternative embodiments of the present invention, if the bit stream is shorter than the burst cycle, the bit stream will be repeated the required number of times for the burst period. It is not necessary that the number of repetitions of the bit stream sequence be equal to a whole number. By using a bit stream having a length similar to that of the burst period, the noise shaping provided can be optimised.

Embodiments of the present invention can be as flexible as required. For example, the ROM 62 may be arranged only to store the channels which the particular receive part and/or the base transceiver station are to provide. Instead, the ROM stores only the bit sequences for those channels which are to be transmitted.

It should be appreciated that if the frequency or frequencies which are to be provided changes the required bit sequences can be simply downloaded to the ROM. In some embodiments of the present invention, this can be done via the base station controller or even a mobile terminal.

An algorithm for generating the bit sequences may be provided in association with the synthesiser. However, in preferred embodiments of the present invention, the ROM or other suitable memory will have an entire bit sequence stored therein before any of the bit sequence is output to the dual modulus divider.

Preferred embodiments of the present invention use a dual modulus divider. However, alternative embodiments of the present invention can use more complicated arrangements which toggle between more than two values. In the preferred embodiments of the present invention which use the dual modulus divider, the two values are preferably N and N+1. However, in alternative embodiments of the present invention, any two integers may be used.

The preferred embodiments use a stream of bits, output one at a time. In more complex arrangements, the output is not binary. In other embodiments of the invention, more than one bit may be output at a time.

The counter and memory of the various embodiments of the present invention may be replaced, in alternative embodiments of the present invention by a FIFO or by any other element able to provide a similar function.

In the embodiment shown in FIG. 4, the channel selection detector may be omitted where a data enable or a synthesizer synchronizer signal is available.

It should be appreciated that the synthesiser shown in embodiments of the present invention has a very broad application and can be used to provide a control signal for a voltage controlled oscillator for any type of arrangement. Embodiments of the present invention are not limited to application in telecommunications systems, wireless or otherwise.

Embodiments of the present invention may provide one or more of the following advantages:

1. Adaptive noise shaping. Each division value can have an independently optimised noise shape,

2. Special noise shaping profiles can be used for known difficult fractional-N division ratios.

3. Alternative noise shaping profiles can easily be down loaded through software control, with the development of better coefficient generating algorithms.

4. This synthesiser can easily be adapted for alternative frequency resolutions, with optimised noise shaping, for other personal communication standards, by changing the values stored in the look up table.

5. Very high sampling frequencies are used, ensuring the first sampling spur will be outside the combination of receiver and transmitter channels, i.e. greater than 200 MHz away from the carrier, in the case of GSM.

6. Higher sampling frequencies offer the greatest improvement of in-band noise performance.

7. Fast lock times can be achieved with excellent phase noise performance reducing the synthesiser's RMS Phase Error and RMS EVM contribution, in the system performance budget.

8. Conventional Sigma-Delta systems calculate their coefficients in-real-time using integer weight and have restricted maximum operating frequencies. This is not the case with embodiments of the invention.

9. This scheme offers higher order noise shaping profiles, without the risk of instability associated with all other Sigma Delta systems.

10. No instability is possible for the digital noise shaping.

11.This approach can easily be adapted to guarantee the Phase Locked Loop's output phase always settles to 0° or a known phase for all output frequencies. Conventional Sigma-Delta architectures cannot easily be reset to zero settling phase, without incurring an unacceptable delay in the phase locking period.

Where embodiments of the present invention are used in telecommunication systems, it should be appreciated that their application is not limited to GSM systems. Embodiments of the present invention can be used with any other suitable standard including analogue standards, standards using time division multiple access, spread spectrum systems such as code division multiple access, frequency division multiple access and hybrids of any two or more of these systems.

The embodiments of the invention have been described as being used in the context of a base transceiver station. However, embodiments of the present invention can also be used in any other suitable receiver or transmitter such as a mobile station.

1. A fractional N frequency synthesizer comprising:
input means for receiving a reference frequency;
output means for providing a desired output frequency;
memory means for storing pre-generated control data for controlling division of the desired output frequency by a plurality of divider values in accordance with the desired output frequency and for providing an output signal generated from the control data;
means for dividing the desired output frequency by the plurality of divider values based on said pre-generated control data stored in the memory means such that when the output signal has a first value, the means for dividing the output frequency divides by a value N and when the output signal has a second value, the means for dividing the output frequency divides by a value N+1.

2. A frequency synthesiser as claimed in claim 1, wherein said memory means comprises a RAM.

3. A frequency synthesiser as claimed in claim 1, wherein said memory means comprises a ROM.

4. A frequency synthesiser as claimed in any preceding claim, wherein said memory means comprises said control data for controlling the dividing means for a plurality of desired output frequencies.

5. A frequency synthesiser as claimed in any preceding claim, wherein address select means are arranged to cause the control data associated with a selected desired output frequency to be output to control said dividing means.

6. A frequency synthesiser as claimed in any preceding claim, wherein said control data is arranged to provide noise shaping.

7. A frequency synthesiser as claimed in any preceding claim, wherein control data is in accordance with sigma delta techniques.

8. A frequency synthesizer as claimed in any of claims 1 to 6, wherein said control data is in accordance with a noise shaping technique with limitless resolution and a choice of non integer weight.

9. A frequency synthesiser as claimed in any preceding claim, wherein the control data is generated by a plurality of different techniques in dependence on the desired frequency.

10. A frequency synthesiser as claimed in any preceding claim, wherein said control data for each frequency comprises a bit sequence.

11. A frequency synthesiser as claimed in claim 10, wherein each bit of said bit sequence is output one by one.

12. A frequency synthesiser as claimed in claim 10 or 11, wherein counter means are provided for clocking the output of each bit of said bit sequence.

13. A frequency synthesizer as claimed in claim 10 or 11, wherein a FIFO is provided for clocking the output of each bit of the bit sequence.

14. A frequency synthesizer as claimed in claims 10, 11, 12 or 13, wherein said memory means is n bits wide, said n bit wide memory means being multiplexed to output said bit sequence.

15. A frequency synthesizer as claimed in claim 14, wherein n is 8 or 16.

16. A frequency synthesiser as claimed in any preceding claim, wherein the synthesiser is arranged when the control data has all been output to output said control data again.

17. A frequency synthesiser as claimed in any preceding claim, wherein said dividing means is arranged to switch between two divider values.

18. A frequency synthesiser as claimed in any preceding claim, wherein said frequency divider values are integers.

19. A frequency synthesiser as claimed in any preceding claim wherein a switching means is a modulus divider.

20. A frequency synthesiser as claimed in any preceding claim, wherein a detector is arranged to receive the reference frequency and the output of said divider means.

21. A frequency synthesiser as claimed in claim 20, wherein said detector is arranged to detect phase information.

22. A frequency synthesiser as claimed in claim 20 or 21, wherein said detector is arranged to detect frequency information.

23. A frequency synthesiser as claimed in any of claims 20 to 22, wherein said detector is arranged to provide an error signal based on the comparison of said output of said switching means and said reference frequency.

24. A frequency synthesiser as claimed in any of claims 20 to 23, wherein the output of the detector is filtered.

25. A frequency synthesiser as claimed in any of claims 20 to 24, wherein the output of said detector is arranged to control a frequency generator.

26. A frequency synthesiser as claimed in claim 25, wherein the frequency generator comprises a voltage controlled oscillator.

27. A frequency synthesiser as claimed in any preceding claim, wherein the output of said synthesiser is input to said dividing means.

28. A frequency synthesiser as claimed in any preceding claim, wherein reset means are provided and are arranged to provide a reset signal relatively shortly after a desired frequency is first selected.

29. A frequency synthesiser as claimed in claim 28, wherein the reset means causes the output of the control data to restart.

30. A frequency synthesiser as claimed in claim 28 or 29, wherein the reset means is arranged to use a submultiple of the reference signal to generate the reset signal.

31. A frequency synthesizer as claimed in claim 30, wherein said submultiple of the reference signal is substantially equivalent to the required output frequency resolution of the synthesizer.

32. A frequency synthesiser as claimed in claim 23 or any claim appended thereto wherein compensation means are provided for removing a modulation component from said error signal.

33. A frequency synthesizer as claimed in any preceding claim, wherein said desired output frequency is a multiple of the reference frequency.

34. A base transceiver station incorporating a frequency synthesiser as claimed in any preceding claim.

35. A mobile station incorporating a frequency synthesiser as claimed in any of claims 1 to 33.
